(19) United States
(12) Patent Application Publication
(10) Pub. No.: US 2020/0273896 A1
(43) Pub. Date: Aug. 27, 2020

(54) IMAGE SENSOR DEVICES AND RELATED METHODS

(71) Applicant: SEMICONDUCTOR COMPONENTS INDUSTRIES, LLC, Phoenix, AZ (US)

(72) Inventors: Manuel H. INNOCENT, Wezemaal (BE); Kevin Alexander STEWART, Gresham, OR (US); David T. PRICE, Gresham, OR (US)

(73) Assignee: SEMICONDUCTOR COMPONENTS INDUSTRIES, LLC, Phoenix, AZ (US)

(21) Appl. No.: 16/506,087

(22) Filed: Jul. 9, 2019

Related U.S. Application Data
(60) Provisional application No. 62/810,370, filed on Feb. 25, 2019.

(51) Int. Cl. H01L 27/146

(52) U.S. Cl. CPC H01L 27/14614; H01L 27/14636; H01L 27/14692; H01L 27/1461

(57) ABSTRACT

Implementations of pixels may include a photodiode layer including a photodetector and two or more silicon based circular transistors and an interconnect layer coupled to the photodiode layer. The interconnect layer may include an amorphous oxide semiconductor (AOS) transistor operatively coupled with the two or more silicon based circular transistors.

### CROSS REFERENCE TO RELATED APPLICATIONS

This application claims the benefit of the filing date of U.S. Provisional Patent Application 62/810,370, entitled “IMAGE SENSOR DEVICES AND RELATED METHODS” to Innocent et al., which was filed on Feb. 25, 2019, the disclosure of which is hereby incorporated entirely herein by reference.

### BACKGROUND

### 1. Technical Field

Aspects of this document relate generally to semiconductor devices, such as image sensors.

### 2. Background

Image sensors are used in a variety of electronic devices, such as vehicles, smart phones, tablets, and other devices having a camera. The image sensors convert light striking a pixel into an electric signal. The electric signal may be processed using a digital signal processor and may be used to make an image.

### SUMMARY

Implementations of a pixel may include a photodiode layer including a photodetector and two or more silicon based circular transistors and an interconnect layer coupled to the photodiode layer. The interconnect layer may include an amorphous oxide semiconductor (AOS) transistor operatively coupled with the two or more silicon based circular transistors.

Implementations of pixels may include one, all, or any of the following:

The AOS transistor may include an indium-gallium-zinc-oxide (IGZO) transistor.

The AOS transistor may be at least partially light shielded by a first metal layer on a first side of the interconnect layer and a second metal layer on a second side of the interconnect layer opposing the first side.

The AOS transistor may be a reset transistor coupled to a floating diffusion.

Implementations of pixel circuits may include a photodetector coupled with a circular transfer gate, one or more amorphous oxide semiconductor (AOS) transistors coupled with a capacitor and with a floating diffusion, and a selection transistor coupled with the floating diffusion and with the one or more AOS transistors.

Implementations of pixel circuits may include one, all, or any of the following:

The circuit may include a second photodetector coupled with a second transfer gate coupled with the floating diffusion.

The second transfer gate may include a circular transfer gate.

The one or more AOS transistors may include one or more indium-gallium-zinc-oxide (IGZO) transistors.

The one or more AOS transistors may include a reset transistor coupled with a gain control transistor.

The selection transistor may be a silicon based transistor.

The one or more AOS transistors may be at least partially light shielded.

The floating diffusion may form an inner connection of the transfer gate.

Implementations of pixel circuits may include a sensor circuit including a photodetector coupled with a reset transistor and a read out transistor and a sample and hold (S/H) stage coupled to the read out transistor. The S/H stage may include an input coupled with the sensor circuit, an amorphous oxide semiconductor (AOS) sample transistor, and a capacitor coupled with the AOS sample transistor. The pixel circuits may also include a buffer circuit coupled with an output of the S/H stage, the buffer circuit including a selection transistor.

Implementations of pixel circuits may include one, all, or any of the following:

The AOS transistor may include an indium-gallium-zinc-oxide (IGZO) transistor.

The S/H stage may include an AOS calibration transistor and a second capacitor.

The circuit may include a precharge circuit coupled to the S/H stage.

The circuit may include one of a second or a second and third AOS sample transistor.

The circuit may include a gain control transistor coupled to the reset transistor.

The AOS sample transistor may be at least partially light shielded by a first and a second metal layer.

The AOS sample transistor may be coupled between the precharge circuit and the sensor circuit.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional side view of an implementation of an interconnect layer of a pixel;

FIG. 2 is a top view of portions of an and implementation of an interconnect layer of a pixel;

FIG. 3 is a top view of a first implementation of a circular transistor;

FIG. 4 is a top view of a second implementation of a circular transistor;

FIG. 5 is a top view of a third implementation of a circular transistor;

FIG. 6 is a diagram of a first implementation of a circuit having an amorphous oxide semiconductor (AOS) transistor;

FIG. 7 is a diagram of a second implementation of a circuit having an AOS transistor;

FIG. 8 is a diagram of a third implementation of a circuit having an AOS transistor;

FIG. 9 is a diagram of a fourth implementation of a circuit having an AOS transistor;

FIG. 10 is a diagram of a fifth implementation of a circuit having an AOS transistor;

FIG. 11 is a diagram of a sixth implementation of a circuit having an AOS transistor;

FIG. 12 is a diagram of a seventh implementation of a circuit having an AOS transistor;

FIG. 13 is a diagram of a eighth implementation of a circuit having an AOS transistor;

FIG. 14 is a diagram of a ninth implementation of a circuit having an AOS transistor;

FIG. 15 is a diagram of a tenth implementation of a circuit having an AOS transistor;

FIG. 16 is a diagram of an eleventh implementation of a circuit having an AOS transistor;

FIG. 17 is a diagram of a first implementation of a photodiode equivalent circuit;

FIG. 18 is a diagram of a second implementation of a photodiode equivalent circuit;

FIG. 19 is a diagram of a third implementation of a photodiode equivalent circuit;

FIG. 20 is a diagram of a first implementation of a transfer gate equivalent circuit;

FIG. 21 is a diagram of a second implementation of a transfer gate equivalent circuit; and

FIG. 22 is a diagram of an implementation of a dual gain circuit.

### DESCRIPTION

This disclosure, its aspects and implementations, are not limited to the specific components, assembly procedures or method elements disclosed herein. Many additional components, assembly procedures and/or method elements known in the art consistent with the intended image sensors will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such image sensors, and implementing components and methods, consistent with the intended operation and methods.

Disclosed herein are implementations of pixels, portions thereof, and circuits thereof. The pixels disclosed herein may be global shutter pixels, overflow based high dynamic range (HDR) pixels, or any other type of pixel. While many of the implementations refer to a single active pixel, it is understood that the pixel may be one of a number of pixels in an array of pixels arranged in multiple rows and multiple columns, each column shared by multiple pixel outputs from the multiple rows of pixels to enable a pipelined or sequential readout of each row of pixels in the array through the shared columns coupled thereto. The array of pixels may be formed in a layer of semiconductor material on a common, shared substrate, which may include other elements and circuits of the image sensor. The semiconductor layer may include, by non-limiting example, silicon, silicon carbide, germanium, indium-gallium-arsenide, any combination thereof, or any other semiconductor material.

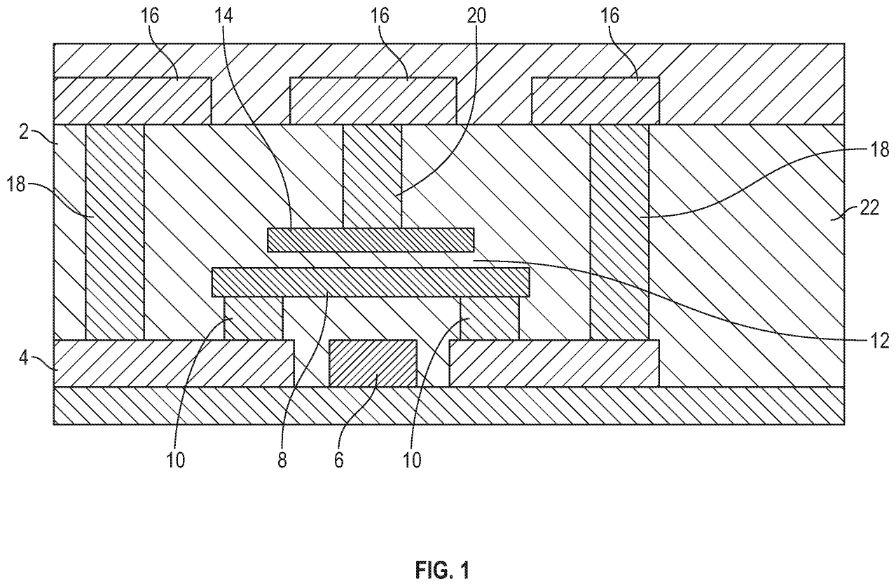

Referring to FIG. 1, a cross sectional side view of an interconnect layer of a pixel is illustrated. The pixel is part of an image sensor, which, in various implementations, may be a front side illumination (FSI) image sensor, or a backside illumination (BSI) image sensor. A photodiode layer (not illustrated) is formed on the other side of the bottom surface of the interconnect layer 2 illustrated in FIG. 1. The interconnect layer 2 acts as the electrical interconnection between the photodiode layer and the various other semiconductor devices of the image sensor including additional semiconductor devices formed in a digital signal processor or other component of an image sensor. As illustrated in FIG. 1, in various implementations the interconnect layer 2 may include a first metal layer 4 on a first side of the interconnect layer. The first metal layer 4 may be patterned and may include any type of metal, alloy thereof, or combination thereof. The first metal layer may include a source 9 and a drain 11 or may be coupled to the source and/or drain portions of a semiconductor transistor device. In particular implementations, the first metal layer 4 may include aluminum. In various implementations, the interconnect layer may also include a back gate 6.

As illustrated in FIG. 1, the interconnect layer may include at least one amorphous oxide semiconductor (AOS) transistor 8 coupled to the first metal layer 4 through a plurality of vias 10. While a particular orientation is illustrated in FIG. 1, this orientation could also be flipped 180 degrees. While the AOS transistor 8 is referred to in reference to the AOS portion, it is understood that other structures illustrated are included in the device itself, including the gate. In various implementations, the AOS transistors disclosed herein may be NMOS-only devices. In particular implementations, the AOS transistor may be coupled to a source through a first via of the plurality of vias and to a drain through a second via of the plurality of vias. The vias may include a conductive material, such as tungsten. Any of the AOS transistors disclosed herein may be thin film transistors. The AOS transistors in various implementations may be dimensionally larger or dimensionally smaller than a silicon based transistor. In particular implementations, the AOS transistor 8 includes an indium-gallium-zinc-oxide (IGZO) transistor. In other implementations, the AOS transistor 8 may include, by non-limiting example, indium-gallium-tin-oxide (IGTO), indium-Sn—Zn—O (ITZO), aluminum-indium-tin-oxide (AITO), boron-indium-zinc-oxide (BIZO), aluminum-indium-tin-zinc-oxide (AITZO, indium-gallium-tin-zinc-oxide (IGTZO), zinc-tin-oxide (ZTO), zinc-indium-oxide (ZIO), indium-tin-oxide (ITO), boron-indium-oxide (BIO), gallium-indium-oxide (GIO), and any combination thereof. While the nomenclature of the AOS transistors disclosed herein include an “oxide” at the end of each name, it is understood that each of the elements within the transistor itself are generally oxides of the elements (for example IGZO includes a mixture of indium oxide, gallium oxide, and zinc oxide). In various implementations, the ratio between the cations of the components of the transistor may be 1:1:1, though in other implementations this ratio may be varied. The AOS transistor may include a single layer or multiple layers formed using various techniques including sputtering of a target with the desired ratio of the cations of the components. In implementations including multiple layers, the layers may be the same or different types of AOS transistor materials. While the implementations of AOS transistors disclosed herein are amorphous, other implementations of transistors may include nanocrystalline material rather than amorphous material. In various implementations, the AOS transistor may be a reset transistor coupled to a floating diffusion.

Still referring to FIG. 1, the interconnect layer 2 may include a dielectric layer 12 (which may be a gate oxide layer) coupled over the AOS transistor. In particular implementations, the dielectric layer may include silicon dioxide, though in other implementations the dielectric layer may include another type of oxide or nitride. In various implementations, and as illustrated by FIG. 1, the interconnect layer 2 material includes a gate 14. The gate 14 is situated over the AOS portion of the transistor 8 and may include an electrically insulative or an electrically conductive material. In particular implementations, the gate 14 may include titanium or titanium nitride. As illustrated in FIG. 1, the interconnect layer 2 includes a second metal layer 16 on a second side of the interconnect layer opposing the first side. The second metal layer 16 may be any type of metal, alloy thereof, or any combination thereof. In particular implementations, the second metal layer 16 may include aluminum. As illustrated, the second metal layer 16 may be patterned. In various implementations the interconnect layer 2 includes a plurality of vias 18 extending from the second metal layer 16 to the first metal layer 4. The interconnect layer may also include one or more vias 20 coupling the second metal layer 16 to the gate 14. As illustrated by FIG. 1, the interconnect layer 2 includes an encapsulant 22. The encapsulant 22 may include an oxide or another electrically insulative material used as an interlayer dielectric. In various implementations, the encapsulant may include a plurality of layers which may be the same type of material or varying types of material.

As illustrated by FIG. 1, because the AOS transistor 8 is within the interconnect layer 2, the AOS transistor 8 may be at least partially light shielded by the structure of the first metal layer 4, the second metal layer 16, the back gate layer 6, and/or the gate electrode layer 14. The light shielding may improve the performance of the pixel by reducing or eliminating electron hole pairs created by photon absorption in the material of the transistor. Further, AOS transistors have an extremely low off-current as compared to silicon based transistors. Because of this, AOS transistors are suited for connections to nodes that need to retain their charge, such as a sample and hold node or a floating diffusion. As illustrated by FIG. 1, because an AOS transistor is coupled to the source and drain, the AOS transistor may reduce the light sensitivity of the source/drain junctions and improve the performance of the pixel. In various implementations, the AOS transistors may have a higher voltage swing as compared to a silicon transistor which may result in an increased dynamic range of the pixel as compared to a pixel not having AOS transistors.

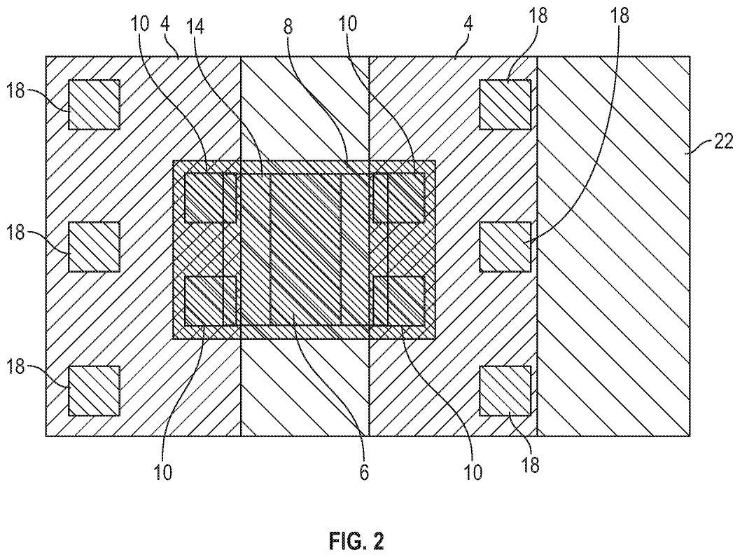

Referring to FIG. 2, a top view of portions of an implementation of an interconnect layer of a pixel is illustrated. FIG. 2 illustrates a top view of the first metal layer 4, the plurality of vias 18, the back gate 6, the AOS transistor 8, the gate 14, the plurality of vias 10, and a portion of the encapsulant 22. The gate 14 and the AOS transistor 8 are illustrated as partially see-through in order to illustrate the back gate 6 and the vias 10 positioned below the gate and the AOS transistor.

Though not illustrated, the pixel includes a photodiode layer coupled under the interconnect layer for a front side illuminated sensor or above the interconnect layer for a backside illuminated sensor. The photodiode layer includes a photodetector configured to detect electromagnetic radiation, or light. In various implementations, the photodiode layer may also include one or more silicon based transistors. The one or more silicon based transistors may be circular/ring/annular transistors. In various implementations all of the transistors in the photodiode layer may be circular, while in other implementations only some of the transistors in the photodiode layer are circular. In more particular implementations, the photodiode layer may include two or more silicon based circular transistors which are operatively coupled with the AOS transistor. In implementations including AOS transistors in the interconnect layer, due to the reduced size of the AOS transistors, the increased size of the circular transistors may not require a larger pixel and the overall pixel fill factor may be the same. Also, in various implementations, the AOS transistors themselves may be stacked within the area of the circular transistors, further permitting the layout of the circuit to be made more compact, despite the larger size of a circular transistor. Accordingly, the combination of AOS transistors and circular transistors in a single pixel may be advantageous as the performance of the pixel improves (as compared to a pixel only having silicon transistors) without requiring a larger pixel. In implementations with a circular transistor, the circular transistor may have less leakage from the transistor as compared to a non-circular silicon based transistor.

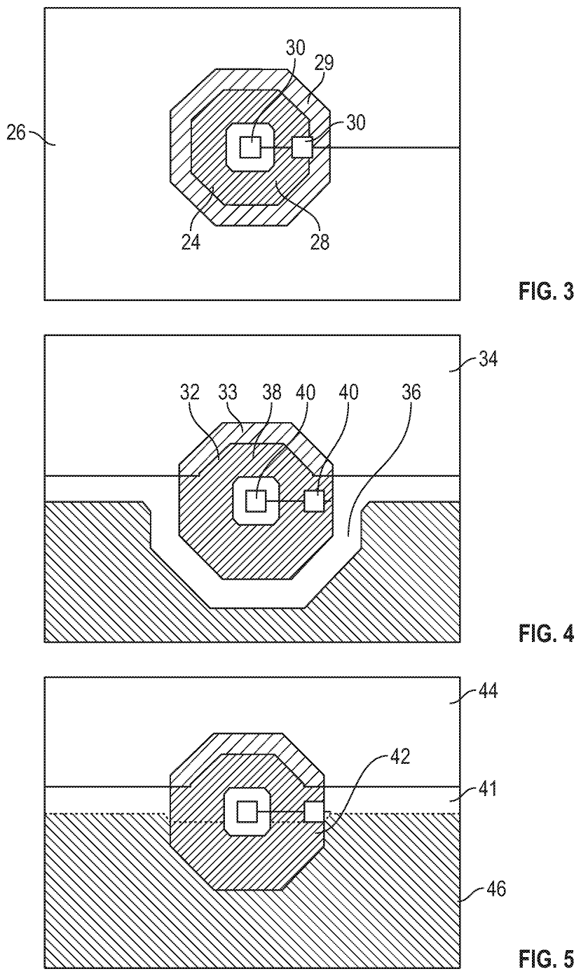

Referring to FIG. 3, a top view of a first implementation of a circular transistor is illustrated. Circular transistors may have very low source/drain junction leakage on the inner connection of the transistor since the inner junction does not interface with shallow trench isolation structures (STI). Further, the implants on the inner connection of the transistor can be optimized for low leakage since the typical trade-offs related to shielding of the STI are absent in a circular transistor design. In FIG. 3, the circular transistor 24 is located fully within a photodiode region 26. The transistor includes a gate 28 and a plurality of contacts 30. As viewed from above, a portion of the photodiode region 26 may overlap with an outer portion of the gate 28 as illustrated by region 29. Referring to FIG. 4, a top view of a second implementation of a circular transistor is illustrated. As illustrated by FIG. 4, the transistor 32 includes a gate 38. The gate 38, as viewed from above, partially overlaps the photodiode region 34 as indicated by region 33. An active area 36 separates the gate from the non-photodiode region. Because the active area 36 extends into the non-photodiode region and because the transistor 32 occupies a just a part of the active area 36, the transistor 32 may take less space in the photodiode region 34. The transistor 32 may also include a plurality of contacts 40. The performance between the transistor illustrated by FIG. 3 may be about equivalent to the performance of the transistor illustrated by FIG. 4. Referring to FIG. 5, a top view of a third implementation of a circular transistor is illustrated. The third implementation illustrated by FIG. 5 may be similar to the implementation illustrated by FIG. 4, with the difference being that there is no active area 41 between the gate region of the transistor 42 and the non-photodiode region 46 as there is in FIG. 4. In various implementations, the performance of the transistor illustrated by FIG. 4 may exceed the performance of the transistor illustrated by FIG. 5 to a certain extent due to the difference in the arrangement of the regions.

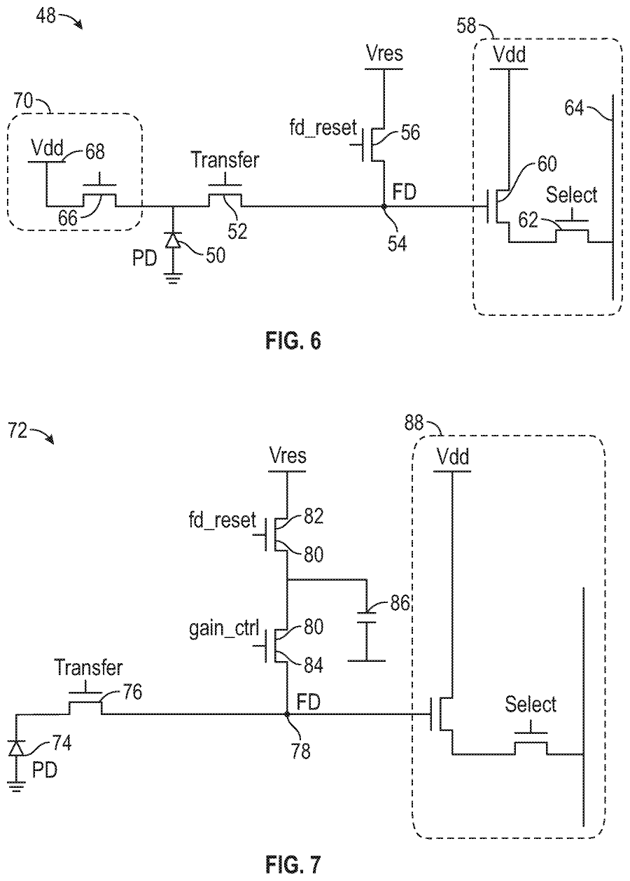

Referring to FIGS. 6-22, various examples of pixel circuit designs and/or portions thereof are illustrated. Any of the pixels disclosed herein may include any of the pixel circuits disclosed herein. Referring to FIGS. 6-9, examples of pixel circuits including a combination of one or more AOS transistors and one or more silicon based circular transistors are illustrated. Referring specifically to FIG. 6, a diagram of a first implementation of a circuit having an AOS transistor is illustrated. The circuit 48 includes a photodetector 50. Though illustrated as a photodiode in the implementations of the circuits disclosed herein, it is understood that the “photodetector” as used herein may include one or more photodiodes, phototransistors, photoresistors, or charge-coupled devices, any of which may be configured to generate changes in current, voltage, or a charge on the photodetector 50 in response to incident electromagnetic radiation of any frequency or wavelength. The photodetector 50 is coupled to a transistor 52 which may serve as the transfer gate. In various implementations, the transistor 52 may be a silicon based circular transistor (or circular transfer gate). In such implementations, the transfer gate may need to be silicon based as it may be coupled with to a fully depletable silicon photodiode. The circuit may also include a floating diffusion 54 which may store a signal of the pixel during exposure of the next signal. In other implementations, rather than a floating diffusion, the circuit may include another similar node, such as a low gain capacitor used to store the signal. In various implementations, the floating diffusion 54 may be the inner connection of the circular transistor 52.

The circuit may include one or more AOS transistors 56, which may be any type of AOS transistor disclosed herein. In various implementations, the AOS transistors 56, and any other AOS transistors disclosed herein, may be light shielded similar to the AOS transistor illustrated by FIG. 1. In various implementations, the one or more AOS transistors 56 may act as a reset transistor. While the circuit illustrated by FIG. 6 only has a single AOS transistor 56, in other implementations, all transistors, which may be more than one, that have a source and/or drain connected to the floating diffusion may be AOS transistors, with the exception of the transfer gate(s). The AOS transistor may reduce leakage of the floating diffusion and improve performance of the pixel as compared to use of a silicon based reset transistor.

Still referring to FIG. 6, in various implementations the circuit 48 includes a buffer circuit 58. The buffer circuit 58 may include a read-out transistor 60. The read-out transistor may be a source follower amplifier. The buffer circuit 58 may also include a selection transistor 62 coupled to the read-out transistor 60. The selection transistor 62 may also be coupled with the floating diffusion 54 and with the one or more AOS transistors 56. The selection transistor 62 may be configured to transfer a voltage at a source of the read-out transistor 60 to the column 64. The read-out transistor 60 and the selection transistor 62 may be AOS transistors or silicon based transistors. In implementations with silicon based read-out and selection transistors, the transistors may or may not be circular. Although circuit 48 is illustrated as including read-out transistor 60, which may be a source follower transistor or amplifier which serves as a buffer, in other implementations other amplifier configurations can also be used to serve as buffers. Such implementations may include the source follower transistor included in a separate circuit between the buffer circuit 58 and the floating diffusion 54. The circuit may also include another transistor 66 coupled to the power source 68. The portion 70 of the circuit including the transistor 66 may or may not be included with the circuit 48. In implementations including the portion 70, the transistor 66 may be an anti-bloom transistor that can reset the photodiode and/or can provide an overflow path for the photodiode when it reaches its maximum charge capacity.

Referring to FIG. 7, a diagram of a second implementation of a circuit having an AOS transistor is illustrated. The circuit 72 of FIG. 7 may be similar to the circuit 48 of FIG. 6. More specifically, the circuit 72 includes a photodetector 74 coupled to a transfer gate 76. The photodetector 74 and the transfer gate 76 may be the same as the photodetector 50 and the transfer gate 52 of FIG. 6 (and both are silicon based devices). The circuit 72 may also include a floating diffusion 78 which may be the same as or similar to the floating diffusion 54 of FIG. 6.

The circuit 72 may include one or more AOS transistors 80, which may be any type of AOS transistor disclosed herein. In various implementations, the one or more AOS transistors 80 may include a reset transistor 82 and a gain control transistor 84. In various implementations, all transistors that have a source and/or drain connected to the floating diffusion may be AOS transistors, with the exception of the transfer gate(s). The AOS transistors may reduce leakage and improve performance of the circuit as compared to use of a silicon transistor. In various implementations, and as illustrated by FIG. 7, the one or more AOS transistors 80 may also be coupled to a capacitor 86. The circuit 72 may also include a buffer circuit 88 which may be the same as or similar to the buffer circuit 58 of FIG. 6.

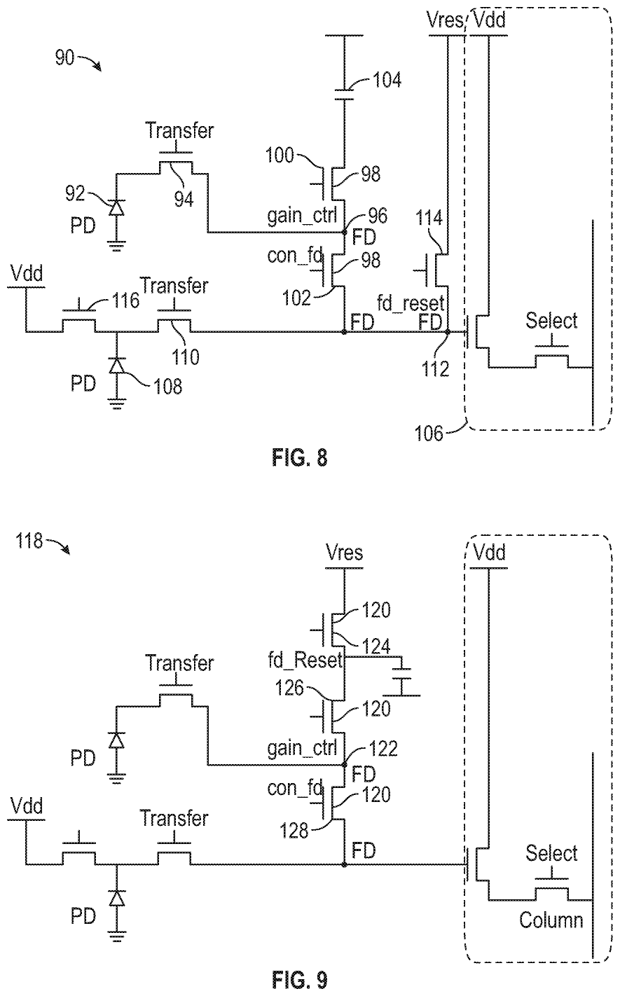

Referring to FIG. 8, a diagram of a third implementation of a circuit having an AOS transistor is illustrated. In various implementations, the circuit 90 may include a first photodetector 92 coupled with a first transfer gate 94. The first photodetector 92 and the first transfer gate 94 may be the same as or similar to any photodetector or transfer gate disclosed herein. More specifically, the transfer gate 94 may be a silicon based circular transistor. The circuit 90 may also include a first floating diffusion 96 which may be the same as or similar to any floating diffusion disclosed herein. In various implementations, the first floating diffusion 96 may be configured to store an overflow signal of the pixel.

The circuit 90 may include one or more AOS transistors 98, which may be any type of AOS transistor disclosed herein. In various implementations, the one or more AOS transistors 98 may include a gain control transistor 100 and a floating diffusion control transistor 102. In various implementations, all transistors that have a source and/or drain connected to the first floating diffusion 96 may be AOS transistors, with the exception of the first transfer gate 94. The AOS transistors may reduce leakage and improve performance of the circuit as compared to use of a silicon transistor. In various implementations, and as illustrated by FIG. 8, the one or more AOS transistors 98 may also be coupled to a capacitor 104. The circuit 90 may also include a buffer circuit 106 which may be the same as or similar to any buffer circuit disclosed herein.

Still referring to FIG. 8, the circuit 90 may include a second photodetector 108 coupled with a second transfer gate 110. The second photodetector 108 may be any type of photodetector disclosed herein. In various implementations, the second transfer gate 110 may be a silicon based non-circular transfer gate. By using the non-circular silicon based transfer gate, the overall capacitance of the system may be reduced. In other implementations, the second transfer gate 110 may be circular and may reduce the leakage from the second transfer gate 110. The second transfer gate 110 may be coupled with a second floating diffusion 112. The second floating diffusion 112 may be the same as or similar to any floating diffusion disclosed herein. A reset transistor 114 may be coupled with the second floating diffusion 112. In various implementations, the reset transistor may be a silicon based transistor, while in other implementations the reset transistor 114 may be an AOS transistor. In implementations where the reset transistor 114 is a silicon based transistor, the capacitance of the system may be reduced, while in implementations having an AOS reset transistor, the leakage of the transistor may be reduced. As illustrated by FIG. 8, the circuit 90 may include a transistor 116 coupled to the second photodetector 108.

Referring to FIG. 9, a diagram of a fourth implementation of a circuit having an AOS transistor is illustrated. The circuit 118 may be similar to the circuit 90 of FIG. 8, with a difference being that the circuit may include a plurality of AOS transistors 120 coupled to a first floating diffusion 122, and the plurality of AOS transistors may include a reset transistor 124 along with a gain control transistor 126 and a floating diffusion connect transistor 128. Accordingly, as illustrated, the reset transistor 124 and associated power source may be coupled to the first floating diffusion region 122 without the floating diffusion connect transistor 128 between the first floating diffusion region 122 and the reset transistor 124. The remainder of the circuit 118 may be the same as or similar to the circuit 90 of FIG. 8.

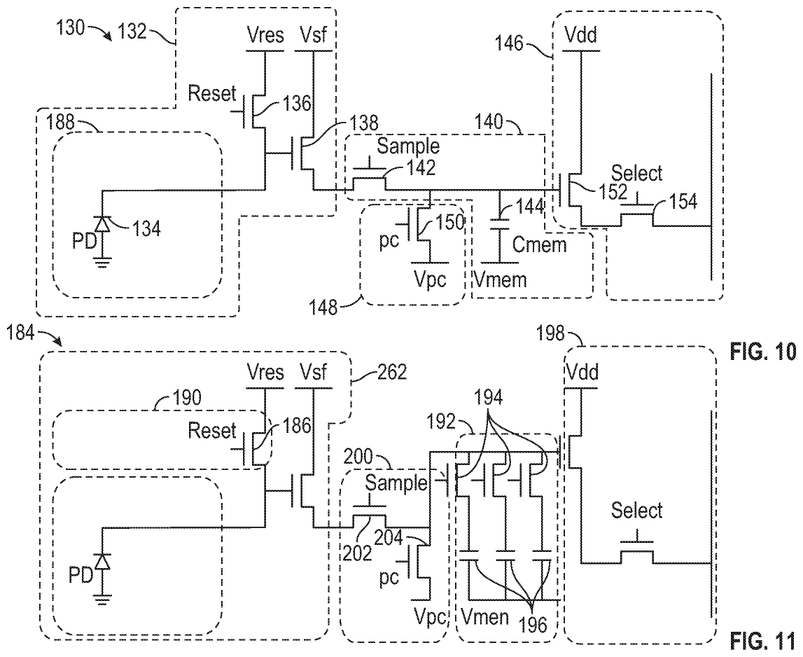

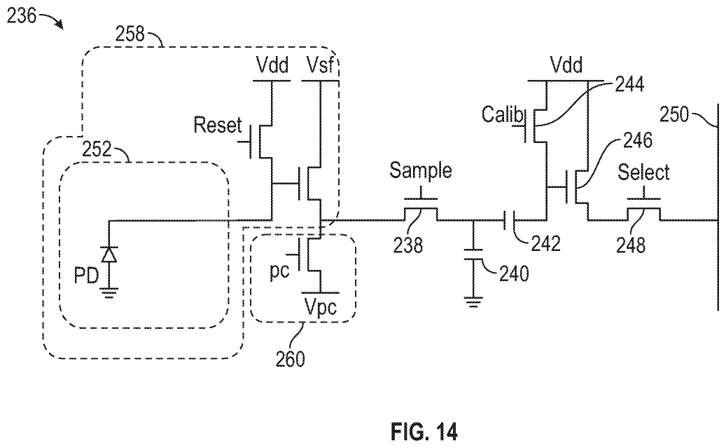

Referring to FIGS. 10-14, various implementations of circuits having AOS transistors without any circular silicon based transistors are illustrated. The circuits of FIGS. 10-13 are implementations of sample and hold circuits. The circuit of FIG. 14 is an implementation of an in-pixel subtraction (CDS) circuit with AOS transistors. The AOS devices of these circuits may improve both the leakage current and the light sensitivity of the sample and hold circuit or CDS circuit due to the very low off-current of the AOS transistor, the lower light sensitivity of the AOS transistor itself, and/or due to the AOS transistor being exposed to reduced light radiation (as explained with regards to FIG. 1). Referring specifically to FIG. 10, a diagram of a fifth implementation of a circuit having an AOS transistor is illustrated. The circuit may include a sensor circuit 132 configured to generate a signal in response to electromagnetic radiation received. The sensor circuit 132 may include a photodetector 134 coupled with a reset transistor 136. The photodetector 134 may be any type of photodetector disclosed herein. The reset transistor 136 may be configured to periodically reset the photodetector 134 to a fixed bias, clearing all accumulated charge on the photodetector at the beginning of every integration period. The sensor circuit 132 may also include a first read-out transistor 138 coupled with the reset transistor. The first read-out transistor may have a drain coupled with Vsf and a source coupled to the input of the S/H stage 140. The read-out transistor 138 may be configured to generate a voltage signal corresponding to the charge accumulated on the photodetector 134, and act as a buffer to enable the charge on the photodetector to be sampled or observed without removing the accumulated charge. In various implementations, the transistors of the sensor circuit 132 may be non-circular silicon based transistors.

The circuit 130 may include a sample and hold (S/H) stage 140 coupled to the read-out transistor 138 and configured to receive an electronic signal from the read-out transistor 138. The S/H stage is configured to sample and temporarily store the signal. The S/H stage 140 includes an input coupled with the sensor circuit 132. The S/H stage 140 also includes an AOS sample transistor 142. The AOS sample transistor may be any type of AOS transistor disclosed herein, and in turn, may be at least partially light shielded by a first and a second metal layer. In implementations including a precharge circuit 148, the sample transistor 142 may be coupled between the precharge circuit 148 and the sensor circuit 132. In various implementations, the S/H stage also includes a capacitor 144 coupled with the AOS sample transistor 142. The AOS sample transistor 142 may improve both the leakage and the light sensitivity of the S/H stage due to low off-current of the AOS transistor and due to the AOS transistor being exposed to little light radiation.

Still referring to FIG. 10, the circuit 130 includes a buffer circuit 146 which may be the same as or similar to any buffer circuit disclosed herein. More specifically, the buffer circuit 146 may include a second read-out transistor 152 and a selection transistor 154. In various implementations, the circuit 130 may also include a precharge circuit 148 coupled to the S/H stage. The precharge circuit may be configured to apply a predefined voltage to the capacitor 144. In other implementations, the precharge circuit may act as a current source. The precharge circuit 148 includes a precharge transistor 150. In various implementations, the precharge transistor 150 may be an AOS transistor including any type of AOS transistor disclosed herein.

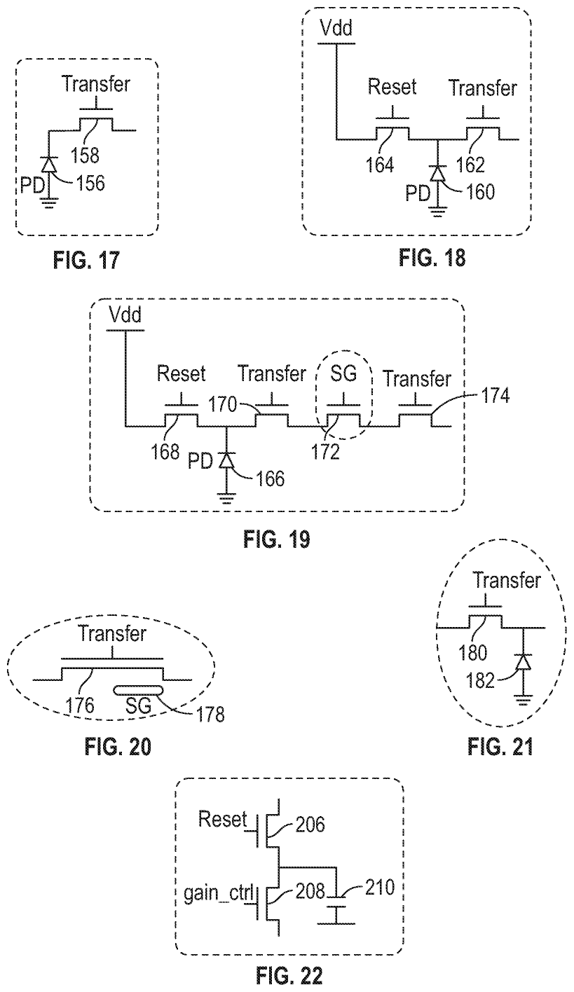

In various implementations, the photodetector 134, or the portion 188 of the circuit 130 may be replaced by any of the different structure implementations illustrated in FIGS. 17-19. Referring specifically to FIG. 17, a diagram of a first implementation of a photodiode equivalent circuit is illustrated. In various implementations the portion 188 of FIG. 10 may include a photodetector 156 coupled to a transfer gate transistor 158. The transfer gate transistor may be a silicon based transistor and may or may not be a circular transistor depending on the system implementation. Referring specifically to FIG. 18, a diagram of a second implementation of a photodiode equivalent circuit is illustrated. In various implementations the portion 188 of FIG. 10 may include a photodetector 160 coupled to a transfer gate transistor 162 and also coupled to a reset transistor 164. The transfer gate transistor 162 and/or the reset transistor 164 may be a silicon based transistor and may or may not be a circular transistor. Referring specifically to FIG. 19, a diagram of a third implementation of a photodiode equivalent circuit is illustrated. In various implementations the portion 188 of FIG. 10 may include a photodetector 166 coupled to a first transfer gate transistor 170, a second transfer gate transistor 174, and a reset transistor 168. In various implementations, the portion 188 of FIG. 10 may also include storage gate transistor 172 coupled between the first transfer gate 170 and the second transfer gate 174. The transistors illustrated by FIG. 19 may be silicon based transistors and may or may not be circular transistors. In various implementations, the first transfer gate 170 of FIG. 19 may include the elements illustrated by FIG. 20 or FIG. 21. Referring specifically to FIG. 20, a diagram of a first implementation of a transfer gate equivalent circuit is illustrated. In various implementations, the first transfer gate 170 of FIG. 19 may include a transfer gate 176 adjacent to a storage gate 178. Referring specifically to FIG. 21, a diagram of a second implementation of a transfer gate equivalent circuit is illustrated. In various implementations, the first transfer gate 170 of FIG. 19 may include a transfer gate 180 coupled with a storage diode 182.

Referring to FIG. 11, a diagram of a sixth implementation of a circuit having an AOS transistor is illustrated. As illustrated, the circuit 184 includes a sensor circuit 262. In various implementations, the sensor circuit 262 may be the same as the sensor circuit 132 of FIG. 10. In other implementations, the reset transistor 186, or portion 190 of the sensor circuit 262 may be replaced by a dual gain circuit. Referring to FIG. 22, a diagram of an implementation of a dual gain circuit is illustrated. In various implementations, the portion 190 of circuit 184 of FIG. 11 may be include a reset transistor 206 coupled to a gain control transistor 208. In various implementations, a capacitor 210 may be coupled with the reset transistor 206 and the gain control transistor 208. In various implementations, any or all of the transistors of FIG. 22 may be silicon based transistors and may or may not be circular transistors.

Referring back to FIG. 11, the circuit 184 may include an S/H stage 192. In various implementations, the S/H stage 192 may include a plurality of sample transistors 194. While FIG. 11 illustrates three sample transistors 194 in the S/H stage 192, other implementations may include more than or less than three sample transistors. The sample transistors may be any type of AOS transistor disclosed herein, and in particular implementations may be IGZO transistors. The S/H stage may also include a plurality of capacitors 196 coupled to the plurality of sample transistors 194. While FIG. 11 illustrates three capacitors in the S/H stage, other implementations may include more than or less than three capacitors in the S/H stage. The number of sample transistors in the S/H stage may correspond with the number of capacitors in the S/H stage.

In various implementations, the circuit 184 includes a buffer circuit 198, which may be the same as or similar to any buffer circuit disclosed herein. In various implementations, the circuit 184 may also include a precharge circuit 200. As illustrated by FIG. 11, the precharge circuit 200 may include a precharge transistor 204 coupled to a sample transistor 202. The precharge circuit may be configured to charge the plurality of capacitors 196. Any and/or all of the transistors of the precharge circuit 200 may be AOS transistors.

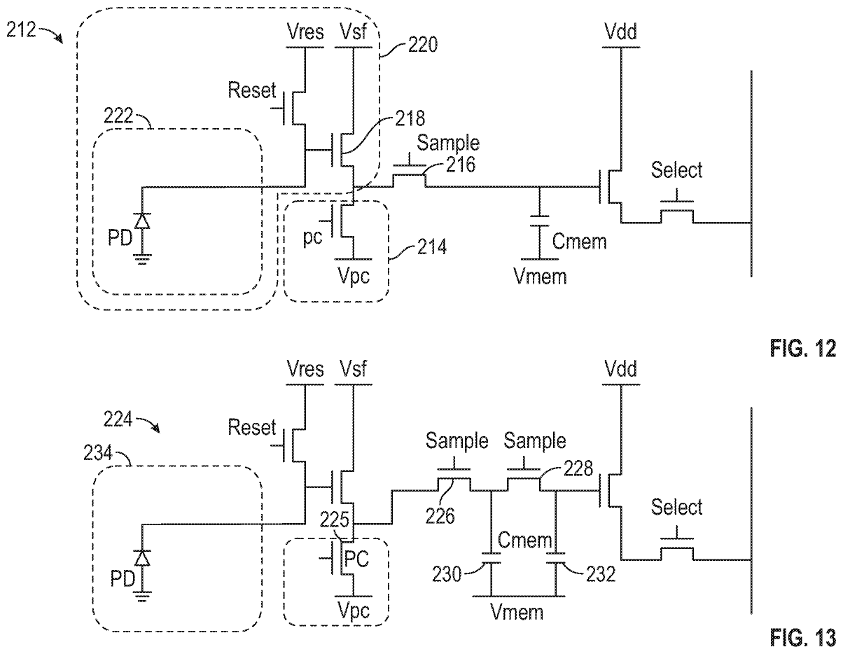

Referring to FIG. 12, a diagram of a seventh implementation of a circuit having an AOS transistor is illustrated. The circuit of FIG. 12 is similar to the circuit of FIG. 10, with the only difference being that the precharge circuit 214 is coupled between the sample transistor 216 (which may be an AOS transistor) and the read-out transistor 218 of the sensor circuit 220. Portion 222 of the circuit may be replaced by any portion illustrated by FIGS. 17-19. Referring to FIG. 13, a diagram of an eighth implementation of a circuit having an AOS transistor is illustrated. The circuit 224 of FIG. 13 may be similar to the circuit 212 of FIG. 12, with the only difference being that circuit 224 includes a first sample transistor 226 coupled with a second sample transistor 228. The circuit also includes a first capacitor 230 and a second capacitor 232 coupled with the first sample transistor 226 and with the second sample transistor 228. The first and second sample transistors may be any type of AOS transistors disclosed herein, including IGZO transistors. Portion 234 of the circuit 224 may be replaced by any of the portions illustrated by FIGS. 17-19. In various implementations, the precharge transistor 225 may be configured to discharge the capacitors 230 and/or 232. In other implementations, the precharge transistor 225 in combination with the capacitors 230 and/or 232 may be configured to act as a current source.

Referring to FIG. 14, a diagram of a ninth implementation of a circuit having an AOS transistor is illustrated. As illustrated, the circuit is a CDS circuit. The circuit 236 includes a sensor circuit 258 which may be the same as any sensor circuit disclosed herein. Likewise, portion 252 of the sensor circuit 258 may be replaced with any of the portions illustrated by FIGS. 17-19. In various implementations, the circuit 236 may also include a precharge circuit 260 which may the same as or similar to any precharge circuit disclosed herein. The circuit 236 also includes a sample transistor 238 coupled to a first capacitor 240 and a second capacitor 242. The circuit 236 may also include a calibration transistor 244 coupled with the second capacitor 242. The calibration transistor 244 couples the second capacitor 242 to a calibration voltage Vdd. The calibration voltage enables capacitor 242 to sample a reset value or signal of the photodetector to be used in generating the signal ultimately selected by the selection transistor 248. The calibration transistor 244 may also be coupled to the power source Vdd which may also be coupled to the read out transistor 246. Any or all of the sample transistor 238 and the calibration transistor 244 may be any type of AOS transistor disclosed herein, including thin film IGZO transistors. The circuit 236 includes a read-out transistor 246 coupled to a selection transistor 248 and a column 250 also coupled to the selection transistor 248. The read-out transistor 246 and the selection transistor 248 may be silicon based transistors, while in other implementations any or all of the read-out transistor and the selection transistor may be AOS transistors.

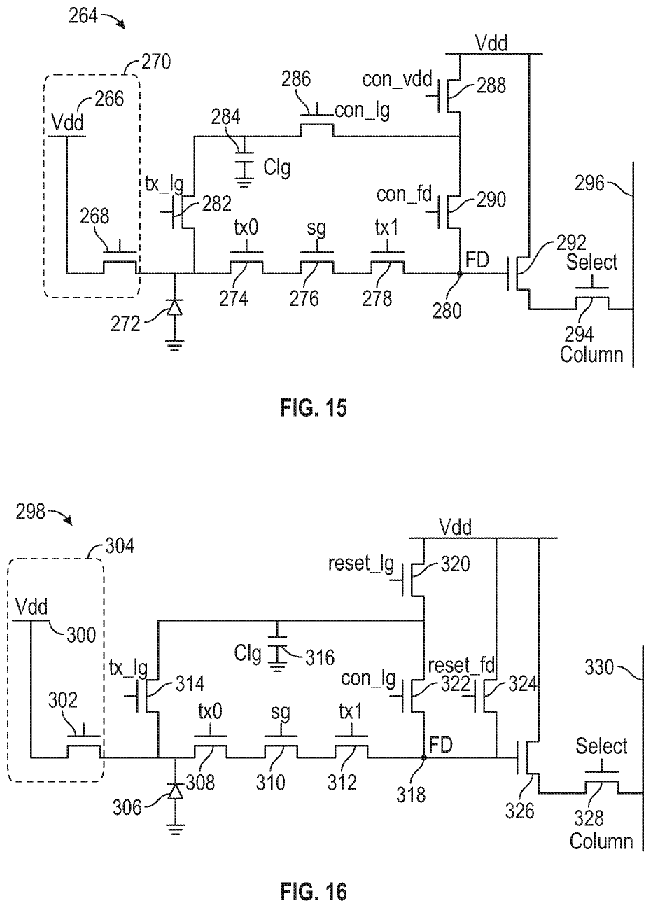

Referring to FIG. 15, a diagram of a tenth implementation of a circuit having an AOS transistor is illustrated. As illustrated, the circuit 264 includes a power source 266 coupled to a transistor 268. The portion 270 of the circuit including the transistor 268 may or may not be included with the circuit 264. In implementations including the portion 270, the transistor 268 may be an anti-bloom transistor that can reset the photodiode and/or can provide an overflow path for the photodiode when it reaches its maximum charge capacity. In various implementations, portion 270 of circuit 264 may be replaced by any circuit illustrated by FIGS. 17-19.

The circuit 264 includes a photodetector 272. The photodetector 272 is coupled to a transistor 274 which may serve as the transfer gate. In various implementations, the transistor 274 may be a silicon based circular transistor (or circular transfer gate) like any disclosed herein. In such implementations, the transfer gate may need to be silicon based as it may be coupled with a fully depletable silicon photodiode. The circuit may also include a storage gate transistor 276 coupled to the transistor 274, and another transistor 278 which may serve as a second transfer gate. Transistors 276 and/or 278 may also be silicon based circuit transistors. The circuit may include a floating diffusion 280. In various implementations, the floating diffusion 280 may be the inner connection of the transistor 278. The floating diffusion 280 may be similar to any other floating diffusion disclosed herein.

In various implementations, the circuit 264 may include a low gain transfer transistor 282 coupled to the photodetector 272. The low gain transfer transistor 282 may be a silicon based transistor and/or a circular transistor like any disclosed herein. The low gain transfer transistor 282 may be configured to set a threshold voltage. The circuit 264 may include a low gain capacitor 284 which may be configured to receive a portion of a signal exceeding the threshold voltage set by the low gain transfer transistor 282. In various implementations, the circuit 264 may include a low gain signal connection transistor 286 coupled to the low gain transfer transistor 282. In various implementations, the low gain signal connection transistor 286 may be an AOS transistor, including any type of AOS transistor disclosed herein. The circuit 264 may also include a connection transistor 288 coupled to a voltage source and the transistor 286. The circuit may also include a connection floating diffusion transistor 290 coupled to the floating diffusion 280 and to the connection low gain transistor 286.

Still referring to FIG. 15, in various implementations the circuit 264 includes a read-out transistor 292. The read-out transistor 292 may be a source follower amplifier. The circuit 264 may also include a selection transistor 294 coupled to the read-out transistor 292. The selection transistor 294 may also be coupled with the floating diffusion 280. The selection transistor 294 may be configured to transfer a voltage at a source of the read-out transistor 292 to the column 296. The read-out transistor 292 and the selection transistor 294 may be AOS transistors or silicon based transistors. In implementations with silicon based read-out and selection transistors, the transistors may or may not be circular. Although circuit 264 is illustrated as including read-out transistor 292, which may be a source follower transistor or amplifier which serves as a buffer, in other implementations other amplifier configurations can also be used to serve as buffers.

In various implementations, the connection low gain transistor 286 may be the only AOS transistor in circuit 264. In other implementations, additional transistors of circuit 264 may also be AOS transistors with the exception of the transfer gate(s). In various implementations, the AOS transistors, may be light shielded similarly to the AOS transistor illustrated by FIG. 1. The AOS transistor may reduce leakage of the floating diffusion and improve performance of the pixel as compared to use of a silicon based reset transistor.

Referring to FIG. 16, a diagram of an eleventh implementation of a circuit having an AOS transistor is illustrated. As illustrated, the circuit 298 includes a power source 300 coupled to a transistor 302. The portion 304 of the circuit including the transistor 302 may or may not be included with the circuit 298. In implementations including the portion 304, the transistor 302 may be an anti-bloom transistor that can reset the photodiode and/or can provide an overflow path for the photodiode when it reaches its maximum charge capacity. In various implementations, portion 304 of circuit 298 may be replaced by any circuit illustrated by FIGS. 17-19.

The circuit 298 includes a photodetector 306. The photodetector 306 is coupled to a transistor 308 which may serve as the transfer gate. In various implementations, the transistor 308 may be a silicon based circular transistor (or circular transfer gate) like any disclosed herein. In such implementations, the transfer gate may need to be silicon based as it may be coupled with a fully depletable silicon photodiode. The circuit may also include a storage gate transistor 310 coupled to the transistor 308, and another transistor 312 which may serve as a second transfer gate. Transistors 310 and/or 312 may also be silicon based circuit transistors. The circuit may include a floating diffusion 280. In various implementations, the floating diffusion 318 may be the inner connection of the transistor 312. The floating diffusion 318 may be similar to any other floating diffusion disclosed herein.

In various implementations, the circuit 298 may include a low gain transfer transistor 314 coupled to the photodetector 306. The low gain transfer transistor 314 may be a silicon based transistor and/or a circular transistor. The low gain transfer transistor 314 may be configured to set a threshold voltage. The circuit 298 may include a low gain capacitor 316 which may be configured to receive a portion of a signal exceeding the threshold voltage set by the low gain transfer transistor 314. In various implementations, the circuit 298 may include a low gain signal reset transistor 320 coupled to the low gain transfer transistor 314. The circuit 298 may also include a low gain signal connection transistor 322 coupled to the low gain signal reset transistor 320. In various implementations, the low gain signal reset transistor 320 and/or the low gain signal connection transistor 322 may be AOS transistors, including any type of AOS transistor disclosed herein. The circuit may also include a floating diffusion reset transistor 324 coupled to the floating diffusion 318.

Still referring to FIG. 16, in various implementations the circuit 298 includes a read-out transistor 326. The read-out transistor 326 may be a source follower amplifier. The circuit 298 may also include a selection transistor 328 coupled to the read-out transistor 326. The selection transistor 328 may also be coupled with the floating diffusion 318. The selection transistor 328 may be configured to transfer a voltage at a source of the read-out transistor 326 to the column 330. The read-out transistor 326 and the selection transistor 328 may be AOS transistors or silicon based transistors. In implementations with silicon based read-out and selection transistors, the transistors may or may not be circular. Although circuit 298 is illustrated as including read-out transistor 326, which may be a source follower transistor or amplifier which serves as a buffer, in other implementations other amplifier configurations can also be used to serve as buffers.

In various implementations, the transistors 320 and/or 322 may be the only AOS transistors in circuit 2298. In other implementations, additional transistors of circuit 298 may also be AOS transistors with the exception of the transfer gate(s). In various implementations, the AOS transistors may be light shielded similar to the AOS transistor illustrated in FIG. 1. The AOS transistor may reduce leakage of the floating diffusion and improve performance of the pixel as compared to use of a silicon based reset transistor.

Various implementations of methods may be employed to form the pixels and pixel circuits disclosed herein. Referring back to FIG. 1, in various implementations a method of forming a pixel may include forming an interconnect layer 2 by providing a first metal layer 4 and patterning the first metal layer. The method may also include forming a back gate 6. In various implementations, the back gate 6 may be formed through patterning the first metal layer 4. The method may also include depositing a first insulative layer which may be an intermetallic dielectric (IMD) layer. In various implementations, the method may include applying a source/drain mask over the first insulative layer and etching a plurality of vias 10 to the first metal layer 4. The vias may be filled with tungsten or another conductive material and the side of first insulative layer through which the vias are exposed may be planarized. The first insulative layer and/or the conductive material may be planarized through chemical-mechanical polishing (CMP).

In various implementations, the method of forming the pixel may include forming an interconnect layer. Such a method may include forming an AOS transistor 8 over the first insulative layer. In particular implementations, the AOS transistor 8 may be an IGZO transistor and may be formed by sputtering a target containing a combination of indium oxide, gallium oxide, and zinc oxide at a desired elemental ratio onto the first insulative layer. The method may include annealing the sputtered material to form the IGZO transistor. Other AOS transistors may be formed using similar methods. In various implementations, the method may include depositing an oxide layer over the AOS transistor 8 and the first insulative layer. In particular implementations, the oxide layer may include silicon dioxide and may act as a gate oxide. The oxide layer may be deposited through chemical vapor deposition (CVD). The method may include applying a mask over the oxide layer and etching the oxide layer and the AOS transistor. In various implementations, the method may include forming a gate 14 over the oxide layer and the AOS transistor 8. The gate may be formed by applying a conductive layer and then patterning and etching the conductive layer. The gate 14 may include TiN or any other conductive material. In various implementations, the method may include depositing a second insulative layer over the gate 14. The second insulative layer may be the same type of material as the first insulative layer. The method of forming the interconnect layer may also include etching a plurality of vias 18 to the first metal layer and one or more vias 20 to the gate 14. The vias 18 and 20 may be filled with a conductive material, such as tungsten, and the side of the second insulative layer and/or conductive material may be planarized using any method disclosed herein. The method of forming the interconnect layer may then include depositing a second metal layer over the second insulative layer and patterning the second metal layer. The second metal layer may include any type of metal or combination thereof disclosed herein.

The method of forming a pixel includes providing a photodiode layer below the interconnect layer 2. The photodiode layer may include one or more photodetectors and one or more transistors, such as a transfer gate transistor. In various implementations, the transistors may be silicon based transistors and may be circular in various implementations. Further, the transistors may be formed to be arranged according to the structures of the circular transistors of any of FIGS. 3-5.

In places where the description above refers to particular implementations of image sensors and implementing components, sub-components, methods and sub-methods, it should be readily apparent that a number of modifications may be made without departing from the spirit thereof and that these implementations, implementing components, sub-components, methods and sub-methods may be applied to other image sensors.

What is claimed is:

1. A pixel comprising:
a photodiode layer comprising a photodetector and two or more silicon based circular transistors; and
an interconnect layer coupled to the photodiode layer, the interconnect layer comprising an amorphous oxide semiconductor (AOS) transistor operatively coupled with the two or more silicon based circular transistors.

2. The pixel of claim 1, wherein the AOS transistor comprises an indium-gallium-zinc-oxide (IGZO) transistor.

3. The pixel of claim 1, wherein the AOS transistor is at least partially light shielded by a first metal layer on a first side of the interconnect layer and a second metal layer on a second side of the interconnect layer opposing the first side.

4. The pixel of claim 1, wherein the AOS transistor is a reset transistor coupled to a floating diffusion.

5. A pixel circuit comprising:
a photodetector coupled with a circular transfer gate;
one or more amorphous oxide semiconductor (AOS) transistors coupled with a capacitor and with a floating diffusion; and
a selection transistor coupled with the floating diffusion and with the one or more AOS transistors.

6. The circuit of claim 5, further comprising a second photodetector coupled with a second transfer gate coupled with the floating diffusion.

7. The circuit of claim 6, wherein the second transfer gate comprises a circular transfer gate.

8. The circuit of claim 5, wherein the one or more AOS transistors comprise one or more indium-gallium-zinc-oxide (IGZO) transistors.

9. The circuit of claim 5, wherein the one or more AOS transistors comprises a reset transistor coupled with a gain control transistor.

10. The circuit of claim 5, wherein the selection transistor is a silicon based transistor.

11. The circuit of claim 5, wherein the one or more AOS transistors are at least partially light shielded.

12. The circuit of claim 5, wherein the floating diffusion forms an inner connection of the transfer gate.

13. A pixel circuit comprising:
a sensor circuit comprising a photodetector coupled with a reset transistor and a read out transistor;
a sample and hold (S/H) stage coupled to the read out transistor, the S/H stage comprising;
an input coupled with the sensor circuit;
an amorphous oxide semiconductor (AOS) sample transistor; and
a capacitor coupled with the AOS sample transistor; and
a buffer circuit coupled with an output of the S/H stage, the buffer circuit comprising a selection transistor.

14. The circuit of claim 13, wherein the AOS transistor comprises an indium-gallium-zinc-oxide (IGZO) transistor.

15. The circuit of claim 13, wherein the S/H stage further comprises an AOS calibration transistor and a second capacitor.

16. The circuit of claim 13, further comprising a precharge circuit coupled to the S/H stage.

17. The circuit of claim 13, further comprising one of a second or a second and third AOS sample transistor.

18. The circuit of claim 13, further comprising a gain control transistor coupled to the reset transistor.

19. The circuit of claim 13, wherein the AOS sample transistor is at least partially light shielded by a first and a second metal layer.

20. The circuit of claim 16, wherein the AOS sample transistor is coupled between the precharge circuit and the sensor circuit.
